(19) United States
(12) Patent Application Publication
(10) Pub. No.: US 2023/0199265 A1
(43) Pub. Date: Jun. 22, 2023

(54) ARRANGEMENT FOR ENHANCING DOWNSTREAM PERFORMANCE

(71) Applicant: Teleste Oyj, Littoinen (FI)

(72) Inventors: Kari MÄKI, Turku (FI); Jonne VUORINEN, Hevonpaa (FI)

(21) Appl. No.: 17/558,933

(22) Filed: Dec. 22, 2021

(51) Int. Cl. H04N 21/61; H04N 17/00

(52) U.S. Cl. CPC H04N 21/6118; H04N 17/00

(57) ABSTRACT

A network element of a cable television (CATV) network, comprising one or more amplifier units for amplifying downstream signal transmission into one or more output channels; a temperature sensor configured to detect one or more of the following: ambient temperature of the network element, and/or one or more of components of the network element; a memory configured to store a predetermined correlation between the detected ambient temperature and a corresponding correction of a bias current for said one or more amplifier units; and a processing unit configured to control the bias current of said one or more amplifier units to be adjusted based on the predetermined correlation.

### FIELD OF THE INVENTION

The invention relates to cable television (CATV) networks, and especially to enhancing the performance of downstream components of network elements.

### BACKGROUND

CATV networks may be implemented with various techniques and network topologies, but currently most cable television networks are implemented as so-called HFC networks (Hybrid Fiber Coax), i.e. as combinations of a fibre network and a coaxial cable network. The terms CATV network, broadband data network and HFC network may be used interchangeably.

Data Over Cable Service Interface Specification (DOCSIS) is a CATV standard providing specifications for high-bandwidth data transfer in an existing CATV system. The latest versions DOCSIS 3.1 and 4.0 enable the cable network operators to significantly increase both the downstream and upstream data throughput using the existing HFC networks. One issue relating to the introduction of DOCSIS 3.1 and the forthcoming 4.0 is the need to eventually adjust the frequency range and the bandwidth of the communication channels. The development of DOCSIS in 3.x and 4.0 versions will require expanding the upper frequency edge of the RF signals to 1.8 GHz, and eventually even over 3 GHz.

Extending the upper frequency edge of the downstream bandwidth closer to 2 GHz poses further challenges. For example, the so-called 1.8 GHz nodes and broadband amplifiers, especially the output amplifier stage therein, needs to be loaded with nearly maximum power level in order to operate properly throughout the downstream bandwidth range. The available margins for adjusting the level are also rather narrow. However, operating the nodes and amplifiers with such high, nearly maximum power levels causes the MER performance of the components of nodes and amplifiers to become very temperature dependent.

Therefore, an improved arrangement is needed for reducing the temperature-dependency of the MER performance of the amplifier components in CATV nodes.

### BRIEF SUMMARY

Now, an improved arrangement has been developed to reduce the above-mentioned problems. As aspects of the invention, we present a network element of a cable television network, which is characterized in what will be presented in the independent claim.

The dependent claims disclose advantageous embodiments of the invention.

The scope of protection sought for various embodiments of the invention is set out by the independent claims. The embodiments and features, if any, described in this specification that do not fall under the scope of the independent claims are to be interpreted as examples useful for understanding various embodiments of the invention.

According to a first aspect of the invention, there is provided a network element of a cable television (CATV) network, said network element comprising one or more amplifier units for amplifying downstream signal transmission into one or more output channels; a temperature sensor configured to detect one or more of the following: ambient temperature of the network element, one or more of components of the network element; a memory configured to store a predetermined correlation between the detected ambient temperature and a corresponding correction of a bias current for said one or more amplifier units; and a processing unit configured to control the bias current of said one or more amplifier units to be adjusted based on the predetermined correlation.

According to an embodiment, said predetermined correlation comprises a network element-specific correlation equation between the detected ambient temperature and the corresponding correction of the bias current, wherein the correlation equation is measured using an output signal characterized by first signal quality criteria.

According to an embodiment, said network element-specific correlation equation comprises a look-up table providing correspondence between the detected ambient temperature and the correction of the bias current.

According to an embodiment, the first signal quality criteria are defined in terms of modulation error ratio (MER).

According to an embodiment, the first signal quality criteria are defined in terms of one or more of the following:
Carrier-to-Intermodulation Noise (CIN),
Carrier-to-Composite Noise (CCN),
Carrier-Interference Noise Ratio (CINR), or
Noise Power Ratio (NPR).

According to an embodiment, the processing unit is configured to control, based on the predetermined correlation, the bias current of said one or more amplifier units to be reduced in response to detecting an increase in the ambient temperature.

According to an embodiment, said amplifier units comprise one or more of the following: a mid-stage amplifier unit, a gain control amplifier unit, a slope control amplifier unit, an output amplifier unit.

According to an embodiment, at least the output amplifier unit is operated on substantially close to a maximum power level.

According to an embodiment, the network element comprises a digital-to-analog converter, wherein said processing unit is configured to provide the digital-to-analog converter with information for adjusting the bias current; and the digital-to-analog converter is configured to provide a voltage configured to adjust the bias current of the output amplifier unit.

According to an embodiment, an upper frequency edge of the downstream frequency band of the network element is 1218 MHz, 1794 MHz or about 3 GHz.

According to an embodiment, the network element comprises a computer program code, stored in a non-transitory memory means, for controlling the processing unit to carry out said adjustments.

These and other aspects, embodiments and advantages will be presented later in the detailed description of the invention.

### BRIEF DESCRIPTION OF THE DRAWINGS

The invention will now be described in more detail in connection with preferred embodiments with reference to the appended drawings, in which:

FIG. 1 shows the general structure of a typical HFC network;

FIGS. 2a and 2b show an example of MER performance of components of a 1.8 GHz CATV node as a function of total composite power (TCP) and ambient temperature of the components tested on lower and higher frequencies, correspondingly;

FIG. 3 shows a MER performance of the output amplifier stage on low frequencies as a function of TCP at different bias current levels according to an embodiment of the invention; and

FIG. 4 shows a simplified block chart of a network element according to an embodiment of the invention.

### DETAILED DESCRIPTION OF THE EMBODIMENTS

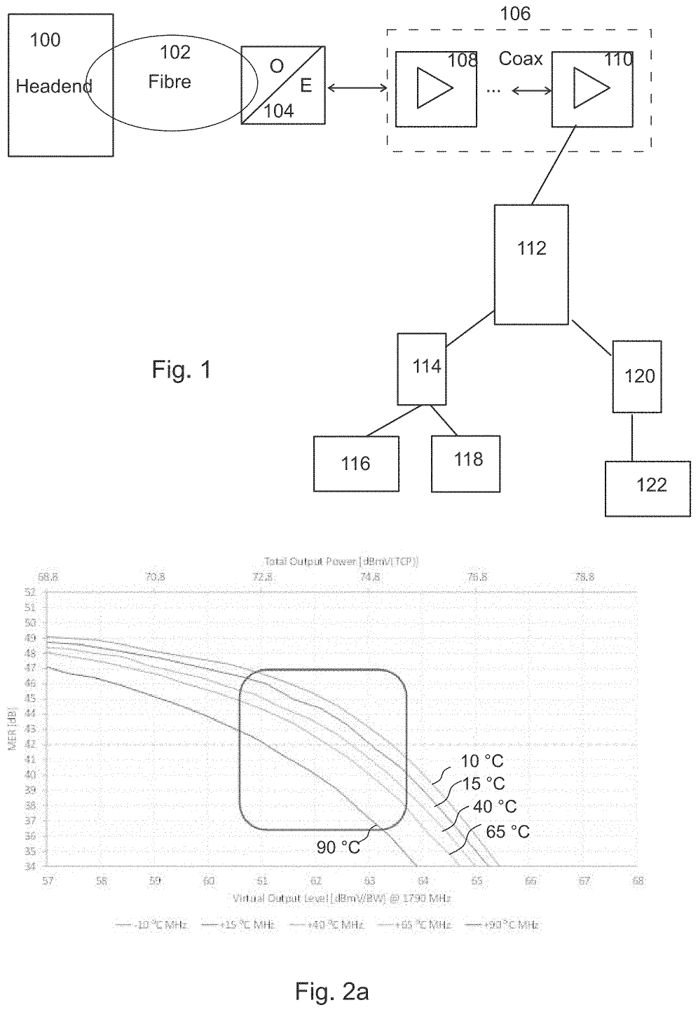

FIG. 1 shows the general structure of a typical HFC network. Program services are introduced from the main amplifier 100 (a so-called headend or CCAP) of the network via an optical fibre network 102 to a fibre node 104, which converts the optical signal to an electric signal to be relayed further in a coaxial cable network 106. Such a node 104 can be an analogue node or a so-called RPD/RMD node. Depending on the length, branching, topology, etc. of the coaxial cable network, this coaxial cable segment typically comprises one or more broadband amplifiers 108, 110 for amplifying program service signals in a heavily attenuating coaxial media. From the amplifier the program service signals are introduced to a cable network 112 of a smaller area, such as a distribution network of an apartment building, which are typically implemented as coaxial tree or star networks comprising signal splitters for distributing the program service signals to each customer. The cable network 112, such as the distribution network of an apartment, may further comprise a Network Interface Unit (NIU) or Point of Entry (PoE) device arranged to divide signals to appropriate home appliances. The NIU may operate as a home amplifier. From a wall outlet the signal is further relayed either via a cable modem 114 to a television receiver 116 or a computer 118, or via a so-called set-top box 120 to a television receiver 122.

The HFC network may be implemented according to various standards. In Europe, video transmission in the HFC networks have traditionally been implemented according to DVB-C (Digital Video Broadcasting-Cable) standard, but currently there is an on-going shift to more widely use the DOCSIS (Data Over Cable Service Interface Specification) standard.

DOCSIS is a CATV standard providing specifications for high-bandwidth data transfer in an existing CATV system. DOCSIS may be employed to provide Internet access over existing hybrid fiber-coaxial (HFC) infrastructure of cable television operators. DOCSIS has been evolved through versions 1.0, 1.1, 2.0, 3.0 and 3.1 to the latest version of 4.0.

When implementing the HFC network of FIG. 1 according to DOCSIS, the headend 100 of the CATV network comprises inputs for signals, such as TV signals and IP signals, a television signal modulator and a cable modem termination system (CMTS). The CMTS provides high-speed data services to customers thorough cable modems (CM; 114) locating in homes. The CMTS forms the interface to the IP-based network over the Internet. It modulates the data from the Internet for downstream transmission to homes and receives the upstream data from homes. The CMTS additionally manages the load balancing, error correction parameters and the class of service (CoS).

Signals from the headend 100 are distributed optically (fiber network 102) to within the vicinity of individual homes, where the optical signals are converted to electrical signals at the terminating points 104. The electrical signals are then distributed to the various homes via the existing 75 ohm coaxial cables 106. The maximum data transfer of the coaxial cables is limited due to strong frequency-based attenuation. Therefore, the electrical signals transmitted over coaxial cables must be amplified. The amplifiers 108, 110 used for this purpose are suited to a specific frequency range. In addition, the upstream and downstream must occur over the same physical connection. The last part 112 of the coaxial connection between the CMTS and the CMs branches off in a star or a tree structure. A CMTS transmits the same data to all CMs located along the same section of cable (one-to-many communications). A request/grant mechanism exists between the CMTS and the CMs, meaning that a CM needing to transmit data must first send a request to the CMTS, after which it can transmit at the time assigned to it.

Depending on the version of DOCSIS used in the CATV network, there is a great variety in options available for configuring the network. For the downstream channel width, all versions of DOCSIS earlier than 3.1 use either 6 MHz channels (e.g. North America) or 8 MHz channels (so-called “EuroDOCSIS”). However, the upstream channel width may vary between 200 kHz and 3.2 MHz (versions 1.0/1.1), and even to 6.4 MHz (version 2.0).

DOCSIS 3.1 specifications support capacities of at least 10 Gbit/s downstream and 1 Gbit/s upstream using 4096 QAM. DOCSIS 3.1 rejects the 6 or 8 MHz wide channel spacing and uses narrower orthogonal frequency-division multiplexing (OFDM) subcarriers being 20 kHz to 50 kHz wide, which subcarriers can be combined within a block spectrum of maximum of 192 MHz wide.

DOCSIS 3.1 further provides the concept of Distributed CCAP Architecture (DCA). Converged Cable Access Platform (CCAP) may be defined as an access-side networking element or set of elements that combines the functionality of a CMTS with that of an Edge QAM (i.e. the modulation), providing high-density services to cable subscribers. Conventionally, the CCAP functionalities have been implemented in the headend/hub, such as the headend 100 in FIG. 1. In a DCA, some features of the CCAP are distributed from headend/hub to the network elements closer to the customers, for example to the fibre nodes 104 in FIG. 1. The CCAP functionalities left to be implemented in the headend/hub may be referred to as CCAP core.

DOCSIS 3.1 specifies at least two network element concepts, i.e. a Remote PHY Device (RPD) and a Remote-MACPHY Device (RMD), to which some functionalities of the headend can be distributed. A recent version of DOCSIS 3.1 specification also provided Annex F introducing a Full Duplex DOCSIS 3.1 technology, where a new distributed access node called Full Duplex (FDX) Node is determined. These network elements implementing at least part of the CCAP functionalities may be referred to as DCA nodes.

One issue relating to the introduction of DOCSIS 3.1 and 4.0 is the need to eventually adjust the frequency range and the bandwidth of the communication channels to meet the requirements of faster communication. The older DOCSIS standards up to the version 3.0 provide an upstream bandwidth of 5-42 MHz (in Americas) or 5-65 MHz (in Europe) and a downstream bandwidth of 85-862 MHz or even up to 1.0 GHz. DOCSIS 3.1 introduces a downstream band up to 1218 MHz. In DOCSIS 3.1, the upper frequency edge of the upstream bandwidth is raised to 204 MHz, causing the lower frequency edge of the downstream bandwidth to be raised to 258 MHz. The development of DOCSIS in 3.x and 4.0 versions will require expanding the upper frequency edge of the RF signals to 1.8 GHz, and eventually even over 3 GHz. In the so-called 1.8 GHz products, the downstream bandwidth range will be 258-1794 MHz.

Typically, most of the CATV amplifiers are configured to align gain and slope at the output such that the output signal has a fixed signal level, which has been aligned at the input side or between forward amplifier stages. The CATV amplifiers typically have forward path amplifier stages including an input amplifier stage, a mid-amplifier stage and an output amplifier stage provided with an output attenuator and an output equalizer. The output amplifier stage, i.e. the so-called output hybrid, is typically configured to provide a very high, nearly maximum signal level to provide a sufficient input level for the next CATV amplifier along the network. However, operating the output amplifier stage close to its maximum values typically causes high power consumption, as well as distortion products possibly degrading the output signal quality.

Extending the upper frequency edge of the downstream bandwidth closer to 2 GHz poses further challenges in this respect. For example, the so-called 1.8 GHz nodes and amplifiers needs to be loaded with nearly maximum power level in order to operate properly throughout the downstream bandwidth range. The available margins for adjusting the level are rather narrow. In terms of TCP (Total Composite Power), this means practical TCP levels of 71-74 dBmV in the final products.

However, operating the nodes with such high, nearly maximum power levels causes the MER performance of the components of nodes to become very temperature dependent.

Modulation error ratio (MER) indicates the deviations of the actual OFDM constellation points from their ideal locations caused e.g. by implementation imperfections or signal path. The modulation error ratio is equal to the ratio of the root mean square (RMS) power (in Watts) of the reference vector to the power (in Watts) of the error. It is defined in dB as: MER (dB)=10 log₁₀ (Pₑᵣᵣₒᵣ/P_{signal}), where Pₑᵣᵣₒᵣ is the RMS power of the error vector, and P_{signal} is the RMS power of ideal transmitted signal. Thus, the smaller the value of MER (dB), the better is the signal quality. In CATV network elements, MER values of <−42 dB, sometimes <−44 dB are typically considered “good enough”, i.e. still allowable.

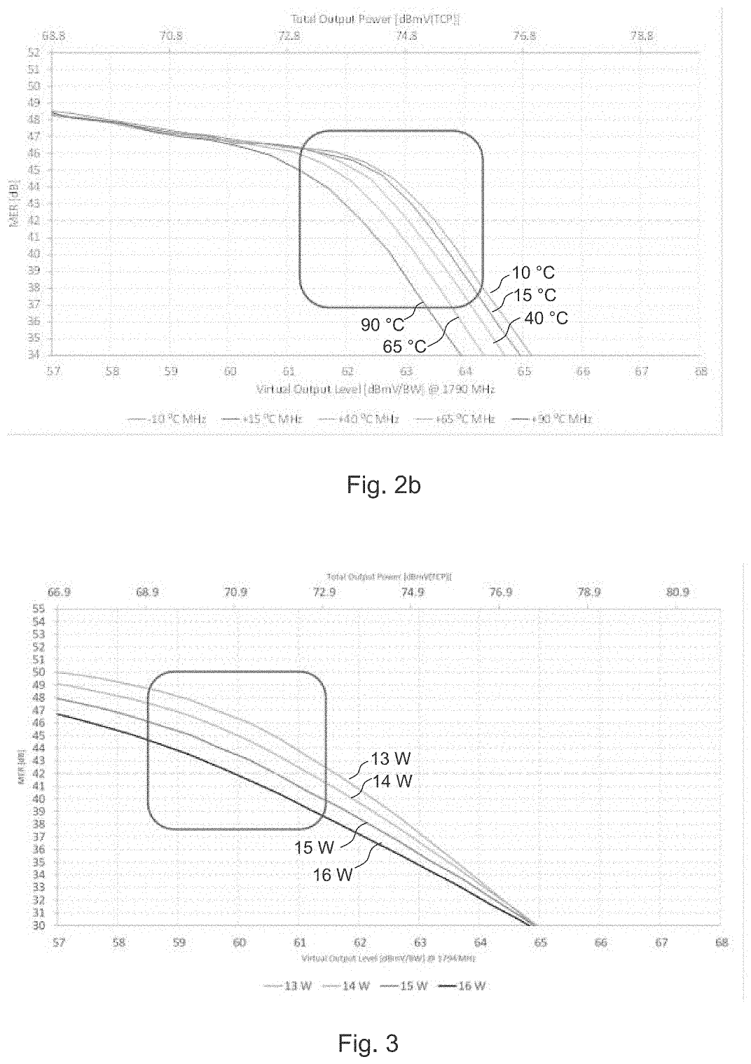

FIGS. 2a and 2b show an example of MER performance of components of a 1.8 GHz CATV product, such as a node or an amplifier, as a function of TCP and ambient temperature of the components. The CATV product is operated on the whole downstream bandwidth range of 258-1794 MHz, and FIG. 2a shows the MER performance on the lower frequencies and FIG. 2b shows the MER performance on the higher frequencies. Both Figures depict five curves illustrating the MER performance as a function of TCP at ambient temperature levels of 10° C., 15° C., 40° C., 65° C. and 90° C., correspondingly. It is noted that ambient temperature 65° C. of the components inside the CATV node typically corresponds to approximately 40° C. ambient temperature of the CATV product. Such temperatures are easily experienced e.g. if the CATV product is exposed to sunlight.

As shown in FIGS. 2a and 2b, the MER performance is very temperature-dependent especially in the operational TCP levels of 71-74 dBmV. FIG. 2a shows that the decline in the MER performance on the lower frequencies starts on TCP levels of below 70 dBmV, and the critical MER level of −42 dB is reached at TCP value of 72.8 dBmV for the ambient temperature level of 90° C. and at TCP value of 74 dBmV for the ambient temperature level of 65° C. On the higher frequencies, in turn, the MER values remain on a rather steady level, but at TCP values higher than 72 dBmV steep temperature-dependent decline is experienced in the MER values.

It is noted that while FIGS. 2a and 2b show only an example relating to MER performance of a particular 1.8 MHz product, similar kind of results can be obtained from other 1.8 MHz products, as well.

Hence, the components of a CATV product may easily experience of drop of 3 dB in the MER performance caused merely by a change in the ambient temperature of the components. In general, it may be approximated that a 3 dB change in MER equals ˜1 bit/Hz. Thus, the loss in bit load over the whole frequency range of 258-1794 MHz amounts up to almost 1.5 Gbps.

Therefore, an improved arrangement is presented herein for compensating for the temperature-dependent nature of the MER performance of the components of products, such as amplifiers and nodes.

According to a first aspect, there is provided a network element of a cable television (CATV) network, said network element comprising one or more amplifier units for amplifying downstream signal transmission into one or more output channels; a temperature sensor configured to detect ambient temperature of the network element and/or one or more of components of the network element; a memory configured to store a predetermined correlation between the detected ambient temperature and a corresponding correction of a bias current for said one or more amplifier units; and a processing unit configured to control the bias current of said one or more amplifier units to be adjusted based on the predetermined correlation.

Thus, the CATV node is provided with a temperature sensor, which is configured to detect ambient temperature of the components of the network element. The components may comprise e.g. the amplifier units or any of their sub-units or components. In addition, or alternatively, the temperature sensor may be configured to detect ambient temperature of the network element itself. However, this information may preferably be converted into an approximation of the ambient temperature of one or more of the components of the network element. For example, as mentioned above, 40° C. ambient temperature of the network element typically corresponds to approximately 65° C. ambient temperature of the components inside the CATV node. Accordingly, since the components of the network element affect directly to the MER performance of the network element, the temperature sensor is intended to obtain a direct measurement or an approximation of the ambient temperature of the components inside the network element.

The network element comprises a predetermined correlation, for example stored in a memory of the network element, where a correspondence between the detected ambient temperature and a corresponding correction of a bias current for said one or more amplifier units is stored. The correlation may be measured and determined, for example upon designing or manufacturing the network element, but preferably at least before installing the network element into the CATV network. Thus, upon detecting a certain ambient temperature, the value for the bias current correction may be checked from said predetermined correlation, and the processing unit may control the bias current of said one or more amplifier units to be adjusted accordingly.

According to an embodiment, said predetermined correlation comprises a network element-specific correlation equation between the detected ambient temperature and the corresponding correction of the bias current, wherein the correlation equation is measured using an output signal characterized by first signal quality criteria.

Thus, the network element may be tested with different values of ambient temperature and different values of bias current and find their correspondence in the equation such that the first signal quality criteria, such as MER, is measured from the output signal. As a result, the correlation is preferably defined in terms of the first signal quality criteria, such as MER, indicating the amount of correction of the bias current at a given ambient temperature needed to provide a desired change in the first signal quality criteria, such as MER.

The correlation equation may be stored in any memory unit of the network element. The correlation equation may be stored, for example, as a function or a curve such that the correspondence between the detected ambient temperature and the corresponding correction of the bias current can be easily determined.

According to an embodiment, said network element-specific correlation equation comprises a look-up table providing correspondence between the detected ambient temperature and the correction of the bias current. Hence, the correlation equation may be stored as a look-up table, from where the correspondence between the detected ambient temperature and the corresponding correction of the bias current can be easily checked.

According to an embodiment, the first signal quality criteria are defined in terms of modulation error ratio (MER). It is, however, noted that MER is only one type of parameter that can be used to measure the underlying problem. The same temperature-dependent behavior can be observed by measuring Carrier-to-Intermodulation Noise (CIN), Carrier-to-Composite Noise (CCN), Carrier-Interference Noise Ratio (CINR), or Noise Power Ratio (NPR), for example. In these tests, an amplifier is loaded with a noise type of signal and distortion products are measured with a spectrum analyzer that has a channel filter at input side. Thus, while the underlying physical phenomena remains the same, the measurements may be different depending on testing capabilities.

According to an embodiment, the processing unit is configured to control, based on the predetermined correlation, the bias current of said one or more amplifier units to be reduced in response to detecting an increase in the ambient temperature.

In normal operation of any amplifier, i.e. also a CATV amplifier, MER values, as well as BER (Bit Error Rate) values, tend to get worse when the ambient temperature is raising, and vice versa, in cold temperature the MER (and BER) performance is typically better. Also in typical adjustments, the increase of bias current usually improves MER/(BER) performance of an amplifier component. On the other hand, the higher ambient temperature typically sets higher requirements for the used operational power (i.e. also for the bias current) of an amplifier.

With these at least partly contradicting preconditions, it has turned out that in the case of at least some component types, instead of increasing the bias current for improving MER in a situation where the high ambient temperature already causes an increase in the power consumption of the amplifier, a reduction in the bias current has a positive impact on the MER performance. It has been noticed that the output amplifier stage used in 1.8 GHz products is not behaving in the assumed way, but rather a reduction of the bias current (i.e. power) in high temperature is needed to improve the MER performance of the output amplifier stage.

FIG. 3 shows the MER performance of the output amplifier stage on low frequencies (corresponding to the frequencies in FIG. 2a) as a function of TCP at different bias current levels, where the output amplifier stage is operating in high ambient temperature. The curves in FIG. 3 depict four different bias current (i.e. power) levels, i.e. 13, 14, 15 and 16 W, and their impact on the MER performance of the output amplifier stage. The impact is especially noticeable at lower frequencies where the fluctuation of the MER performance is larger. As can be seen in FIG. 3, in typical TCP values the reduction of bias current (i.e. power) level from 16 W to 13 W produces approximately 4 dB improvement in the MER performance.

According to an embodiment, said amplifier units comprise one or more of the following: a mid-stage amplifier unit, a gain control amplifier unit, a slope control amplifier unit, an output amplifier unit. The CATV node or amplifier typically includes a plurality of amplifier units on the downstream signal path, which each may be provided with a bias current, but most obvious results in terms of improving the MER performance are obtained by adjusting the bias current of the output hybrid amplifier unit typically consuming a major part of power of the CATV node. It is noted that the output amplifier unit may also be implemented as a microwave monolithic integrated circuit (MMIC) or a MultiChip Module (MCM) amplifier circuit.

According to an embodiment, the network element comprises a digital-to-analog converter, wherein said processing unit is configured to provide the digital-to-analog converter with information for adjusting the bias current; and the digital-to-analog converter is configured to provide a voltage configured to adjust the bias current of the output amplifier unit.

Thus, a digital-to-analog converter (DAC) may be utilised in providing the adjusted bias current to the output (hybrid) amplifier unit. The processing unit obtains information about the ambient temperature from the temperature sensor and based on the information, the processing unit determines a control signal to be sent to the DAC. The DAC creates a voltage based on the control signal, which when applied over a resistance creates a bias current to be supplied to the output (hybrid) amplifier unit.

It is noted that while the embodiments are described herein using a 1.8 GHz network element as an illustrative example, the embodiments are equally applicable to any network element, especially an amplifier, where the amplifier units need to be loaded with nearly maximum power level in order to operate properly throughout the downstream bandwidth range. Thus, the embodiments may be applicable to corresponding network elements operating according to DOCSIS 3.1, where the upper frequency edge of the downstream frequency band is about 1.2 GHz (1218 MHz). Especially, the embodiments are applicable to corresponding network elements operating according to DOCSIS 4.0 where the upper frequency edge of the downstream frequency band may be about 3.0 GHz.

It is further noted that embodiments are applicable also in a situation, where only a part of the nominal downstream frequency band is in use. The used downstream frequency band may extend, for example, to about 1.5 GHz, for various reasons, even if the upper edge of nominal downstream frequency band were 1.8 GHz. Even in such situation the amplifier units may need to be loaded with nearly maximum power level in order to operate properly throughout the downstream bandwidth range currently in use.

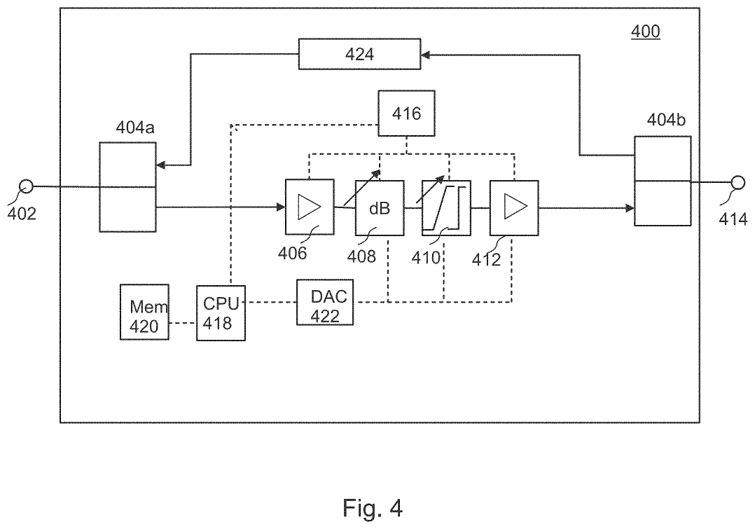

FIG. 4 shows an example of a simplified block chart of a network element, i.e. a CATV amplifier, according to an embodiment. FIG. 4 shows a simplification of the downstream path within the amplifier; thus, no separate components relating to upstream path are shown, but they are commonly referred to with the reference number 426. It is further noted that while FIG. 4 shows the implementation in a broadband amplifier, the embodiments are equally applicable, for example, in a DCA device, such as an RPD/RMD node or an FDX node.

The CATV amplifier 400 comprises a first input/output port 402, which operates as an input for the downstream signals originating from the headend or the CMTS or the CCAP core and an output for the upstream signals originating from the customer devices. The amplifier 400 further comprises a second input/output port 414, which operates as an output for the downstream signals originating from the headend or the CMTS and an input for the upstream signals originating from the customer devices. Both ports 402, 414 are provided with at least one diplex filter 404a and 404b, respectively, for filtering the downstream signals and the upstream signals to their respective frequency bands and splitting the downstream and upstream signals to their own signal routes. The upstream path components are commonly referred to with the reference number 424

The downstream signal path of the network element typically comprises a plurality of amplifier units along the downstream path. There may be one or more mid-stage amplifier units 406, a gain control amplifier unit 408, a slope control amplifier unit 410 and the output hybrid amplifier unit 412. The amplified downstream signals are supplied via the diplex filter 404b and the second input/output port 414 further to a network segment. A temperature sensor 416 may be configured to detect ambient temperature of the output hybrid amplifier unit 412, ambient temperatures of each of the amplifier units 406-412 separately, or ambient temperature of the CATV broadband amplifier as such.

The CATV amplifier 400 may comprise a processing unit (CPU) 418 for controlling the operation of at least some of components of the CATV amplifier. The CATV amplifier 400 may comprise a memory 420, where the predetermined correlation between the detected ambient temperature and the corresponding correction of the bias current for said one or more amplifier units is stored.

The processing unit 418 obtains the ambient temperature measurement from the temperature sensor 416. The processing unit 418 obtains the predetermined correlation from the memory 420 and checks the bias current corresponding to the detected ambient temperature. The processing unit 418 may create a control signal indicative of the correction of the bias current to a digital-to-analog converter (DAC, 422). Now, on the basis of the control signal, the DAC 422 may create a voltage, which when applied over a resistance (e.g. within the DAC) creates a bias current to be supplied to one or more of these amplifier units, but preferably at least to the output hybrid amplifier unit. The adjustment, such as a reduction, of the bias current of one or more of the amplifier units preferably causes an improvement in the MER performance of the amplifier unit, even when operated in high ambient temperature. The number of amplifier units is not limited, but in practical implementations, the number of amplifier units whose bias current is adjusted is typically from one to four.

As mentioned above, the embodiments are equally applicable in any DCA or non-DCA node producing either digital or analogue output signals. For example, the embodiments may be applied in analogue nodes and broadband amplifiers, or in an RPD/RMD node or an FDX node. If implemented in an analogue node or amplifier, the bias control circuit can be implemented by discrete analogue components, such as operational amplifiers, combined with a temperature sensor, i.e. without any of a processor, a memory and/or a DAC.

In general, the various embodiments may be implemented in hardware or special purpose circuits or any combination thereof. While various embodiments may be illustrated and described as block diagrams or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

A skilled person appreciates that any of the embodiments described above may be implemented as a combination with one or more of the other embodiments, unless there is explicitly or implicitly stated that certain embodiments are only alternatives to each other.

According to an embodiment, the network element comprises a computer program code, stored in a non-transitory memory means, for controlling the processing unit to carry out said adjustments.

The various embodiments can be implemented with the help of computer program code that resides in a memory and causes the relevant apparatuses to carry out the invention. Thus, the implementation may include a computer readable storage medium stored with code thereon for use by an apparatus, such as the network element, which when executed by a processor, causes the apparatus to perform the various embodiments or a subset of them. In addition, or alternatively, the implementation may include a computer program embodied on a non-transitory computer readable medium, the computer program comprising instructions causing, when executed on at least one processor, at least one apparatus to perform the various embodiments or a subset of them. For example, an apparatus may comprise circuitry and electronics for handling, receiving and transmitting data, computer program code in a memory, and a processor that, when running the computer program code, causes the apparatus to carry out the features of an embodiment.

It will be obvious for a person skilled in the art that with technological developments, the basic idea of the invention can be implemented in a variety of ways. Thus, the invention and its embodiments are not limited to the above-described examples, but they may vary within the scope of the claims.

1. A network element of a cable television (CATV) network, said network element comprising
one or more amplifier units for amplifying downstream signal transmission into one or more output channels;
a temperature sensor configured to detect one or more of the following: ambient temperature of the network element, one or more of components of the network element;
a memory configured to store a predetermined correlation between the detected ambient temperature and a corresponding correction of a bias current for said one or more amplifier units; and
a processing unit configured to control the bias current of said one or more amplifier units to be adjusted based on the predetermined correlation.

2. The network element according to claim 1, wherein said predetermined correlation comprises a network element-specific correlation equation between the detected ambient temperature and the corresponding correction of the bias current, wherein the correlation equation is measured using an output signal characterized by first signal quality criteria.

3. The network element according to claim 2, wherein said network element-specific correlation equation comprises a look-up table providing correspondence between the detected ambient temperature and the correction of the bias current.

4. The network element according to claim 2, wherein the first signal quality criteria are defined in terms of modulation error ratio (MER).

5. The network element according to claim 2, wherein the first signal quality criteria are defined in terms of one or more of the following:
Carrier-to-Intermodulation Noise (CIN),
Carrier-to-Composite Noise (CCN),
Carrier-Interference Noise Ratio (CINR), or
Noise Power Ratio (NPR).

6. The network element according to claim 1, wherein the processing unit is configured to control, based on the predetermined correlation, the bias current of said one or more amplifier units to be reduced in response to detecting an increase in the ambient temperature.

7. The network element according to claim 1, wherein said amplifier units comprise one or more of the following: a mid-stage amplifier unit, a gain control amplifier unit, a slope control amplifier unit, an output amplifier unit.

8. The network element according to claim 7, wherein at least the output amplifier unit is operated on substantially close to a maximum power level.

9. The network element according to claim 7, comprising a digital-to-analog converter, wherein
said processing unit is configured to provide the digital-to-analog converter with information for adjusting the bias current; and
the digital-to-analog converter is configured to provide a voltage configured to adjust the bias current of the output amplifier unit.

10. The network element according to claim 1, wherein an upper frequency edge of the downstream frequency band of the network element is 1218 MHz, 1794 MHz or about 3 GHz.

11. The network element according to claim 1, comprising
a computer program code, stored in a non-transitory memory means, for controlling the processing unit to carry out said adjustments.
